(19) United States
(12) Patent Application Publication
(10) Pub. No.: US 2024/0120418 A1
(43) Pub. Date: Apr. 11, 2024

(54) LDMOS SEMICONDUCTOR DEVICE AND METHOD OF MANUFACTURING THE SAME

(71) Applicant: DB HiTek Co., Ltd., Bucheon-si (KR)

(72) Inventor: Sang II HWANG, Wonju-si (KR)

(21) Appl. No.: 18/191,296

(22) Filed: Mar. 28, 2023

(30) Foreign Application Priority Data
Oct. 6, 2022 (KR) 10-2022-0127497

(51) Int. Cl. H01L 29/78; H01L 21/761; H01L 29/66

(52) U.S. Cl. CPC H01L 29/7816; H01L 21/761; H01L 29/66681

(57) ABSTRACT

Disclosed is an LDMOS semiconductor device and a method of manufacturing the same and, more particularly, to an LDMOS semiconductor device and a method of manufacturing the same seeking to maintain a high breakdown voltage while reducing the chip size through non-formation or size minimization of an extension region, and thus improving the degree of integration, by forming or including a deep trench isolation (DTI) region along the width or similar lateral direction of the LDMOS semiconductor device, on a longitudinal boundary of a core region.

### CROSS REFERENCE TO RELATED APPLICATION

The present application claims priority to Korean Patent Application No. 10-2022-0127497, filed Oct. 6, 2022, the entire contents of which are incorporated herein for all purposes by this reference.

### BACKGROUND OF THE INVENTION

### Field of the Invention

The present disclosure relates to a lateral double-diffused metal-oxide-semiconductor (LDMOS) semiconductor device and a method of manufacturing the same and, more particularly, to an LDMOS semiconductor device and a method of manufacturing the same seeking to maintain high breakdown voltage characteristics while reducing the chip size through non-formation or size minimization of an extension region and thus improving the degree of integration by forming or including a DTI (deep trench isolation) region extending along the width direction on the longitudinal boundary of a core region.

### Description of the Related Art

A high voltage lateral double-diffused metal-oxide-semiconductor (LDMOS) transistor has advantages such as fast switching speed, high input impedance, low power consumption, and compatibility with CMOS processing. LDMOS transistors are used in a variety of power devices, including display driver ICs, power converters, motor controllers, and automotive power supplies.

FIG. 1 is a plan view of a conventional LDMOS semiconductor device.

Hereinafter, the structure and problems of a conventional LDMOS device 9 will be described in detail with reference to FIG. 1.

Referring to FIG. 1, a core region C includes a source 910 and a drain 930 spaced apart from each other along a width direction in an active region of a limited size defined by a device isolation layer. An extension region D is at each end of the core region C in a longitudinal direction. The gate electrode 950 in the core region C has two parts extending in the longitudinal direction and, in each of the extension regions D, a curved part connecting the parts in the core region C to each other. That is, the gate electrode 950 has a closed path in a plan view.

In addition, a second conductivity type well 970 is in the core region C and the extension regions D. A device isolation layer 990, which comprises a shallow trench isolation (STI) structure, may surround the well 970. The STI structure may be in an isolation region I.

Thus, the core region C, the extension region D, and the isolation region I may be along the longitudinal direction of the conventional LDMOS device 9. In the conventional LDMOS device 9, since the electric field concentration at the ends of the source 910 and the drain 930 (e.g., near the interfaces between the extension regions D and the core region C) acts as a factor limiting breakdown voltage of the LDMOS device, the extension regions D extend from each end of the core region C in the longitudinal direction to the isolation region I.

The extension region D improves the breakdown voltage of the LDMOS device, but increases the chip size of the LDMOS device 9. Moreover, when the LDMOS device 9 is multi-fingered, the extension regions D in the device are repeated in addition to the core region C, which inevitably increases the size of the power circuitry more than necessary. For example, the extension regions D and isolation regions I of the adjacent devices (e.g., along the longitudinal direction) inevitably overlap. That is, when a LDMOS cell is multi-fingered within a limited area, the extended region D where there is no channel region is also repeated. This increases the size of the power circuitry and becomes a factor in increasing the overall manufacturing cost.

To solve the above-mentioned problems, the present disclosure concerns an LDMOS semiconductor device having a novel structure and a method of manufacturing the same.

### DOCUMENT OF RELATED ART

Korean Patent Application Publication No. 10-2003-0000592, entitled “METHOD FOR MANUFACTURING SEMICONDUCTOR DEVICE WITH STI/DTI STRUCTURE.”

### SUMMARY OF THE INVENTION

The present disclosure has been made to solve the problems of the related art, and an objective of the present disclosure is to provide an LDMOS semiconductor device and a method of manufacturing the same seeking to maintain a high breakdown voltage while reducing the chip size through non-formation or size minimization of an extension region (e.g., of the LDMOS semiconductor device) and thus improving the degree of integration by forming or including a deep trench isolation (DTI) structure along a width direction (e.g., of the LDMOS semiconductor device) on the longitudinal boundary of a core region (e.g., of the LDMOS semiconductor device).

In addition, an objective of the present disclosure is to provide an LDMOS semiconductor device and a method of manufacturing the same seeking to prevent an increase in device size due to the formation or inclusion of a DTI structure by forming or including the DTI structure in a device isolation layer.

Furthermore, an objective of the present disclosure is to provide an LDMOS semiconductor device and a method of manufacturing the same seeking to form a DTI structure in two stages or include a DTI structure having an upper section and a lower section so that the DTI structure extends deeply into the substrate.

According to an embodiment of the present disclosure, there is provided an LDMOS semiconductor device, including a core region including a source and a drain spaced apart from each other (e.g., along a width of the LDMOS semiconductor device, or similar lateral direction); an isolation region (e.g., spaced apart from a longitudinal end of the core region); and an extension region between the core region and the isolation region, wherein the core region may include a pair of gate electrodes on opposite sides of the source and on a substrate, wherein the pair of gate electrodes may extend through the core region (e.g., along a length of the LDMOS semiconductor device, or similar longitudinal direction) to the extension region and are not directly connected to each other.

According to another embodiment of the present disclosure, in the LDMOS semiconductor device, the isolation region may include a deep trench isolation (DTI) structure extending along a boundary of the extension region (e.g., adjacent to the core region, along an interface between the extension region and the isolation region, and/or along the width or similar lateral direction of the LDMOS semiconductor device).

According to still another embodiment of the present disclosure, in the LDMOS semiconductor device, the isolation region may further include a device isolation layer comprising a shallow trench isolation (STI) structure, wherein the DTI structure may at least partially overlap the device isolation layer.

According to still another embodiment of the present disclosure, in the LDMOS semiconductor device, the DTI structure may include an upper section overlapping with the device isolation layer but having a smaller width than the device isolation layer; and a lower section extending from the upper section (e.g., from a lowermost surface thereof).

According to still another embodiment of the present disclosure, in the LDMOS semiconductor device, the lower section may have a smaller width than the upper section.

According to still another embodiment of the present disclosure, there is provided an LDMOS semiconductor device, including a deep well, comprising a first impurity doped region in a substrate; a first well and a second well, respectively comprising second and third impurity doped regions in the deep well; a drain in the first well; a body region in the substrate, comprising a fourth impurity doped region spaced apart from the deep well; a source in the body region; a gate electrode spaced apart from the source and drain on the substrate; and a deep trench isolation (DTI) structure in the substrate, wherein the gate electrode and the deep well may have no closed path.

According to still another embodiment of the present disclosure, the LDMOS semiconductor device may further include a device isolation layer surrounding the deep well.

According to still another embodiment of the present disclosure, in the LDMOS semiconductor device, the DTI structure may limit a longitudinal extension of the deep well.

According to still another embodiment of the present disclosure, in the LDMOS semiconductor device, the DTI structure may be on or adjacent to a boundary of a core region or an isolation region (e.g., of the LDMOS semiconductor device).

According to still another embodiment of the present disclosure, the LDMOS semiconductor device may comprise a pair of DTI structures, on or adjacent to opposite ends or boundaries of the core region, the pair of DTI structures being spaced apart from each other, and optionally extending along a width direction (e.g., of the LDMOS semiconductor device).

According to still another embodiment of the present disclosure, the LDMOS semiconductor device may further include a first buried layer and a second buried layer in the substrate; and a high voltage well connected to the second buried layer (and, optionally, a well, such as the deep well).

According to still another embodiment of the present disclosure, there is provided an LDMOS semiconductor device, including a deep well in a core region, comprising a first impurity doped region in a substrate; a first well comprising a second impurity doped region in the deep well; a drain in the first well and in the core region; a body region in the core region, comprising a third impurity doped region in the substrate; a source in the body region (and, e.g., in only the core region); a gate electrode on the substrate (e.g., along a length or similar longitudinal direction of the LDMOS semiconductor device); a device isolation layer in each of two isolation regions (e.g., at opposite ends of the core region), surrounding the deep well (e.g., between the deep well and a peripheral edge of the LDMOS semiconductor device); and a deep trench isolation (DTI) structure in (each of) the isolation region(s), near or adjacent to a boundary of the core region, wherein the pair of DTI structures may be spaced apart along the length or similar longitudinal direction of the LDMOS semiconductor device.

According to still another embodiment of the present disclosure, in the LDMOS semiconductor device, the pair of DTI structures may be directly connected to each other.

According to still another embodiment of the present disclosure, in the LDMOS semiconductor device, the pair of DTI structures may extend substantially parallel along a width or similar lateral direction of the LDMOS semiconductor device.

According to still another embodiment of the present disclosure, in the LDMOS semiconductor device, the gate electrode and the deep well may have no closed path.

According to still another embodiment of the present disclosure, in the LDMOS semiconductor device, the pair of DTI structures may have ends in a width direction connected to each other on or in the device isolation layer.

According to still another embodiment of the present disclosure, in the LDMOS semiconductor device, each of the pair of DTI structures may include an upper section at least partially overlapping the device isolation layer and having a smaller width than the device isolation layer; and a lower section continuous with the upper section and having an end deeper (e.g., into the substrate) than the lowermost surface of the upper section, wherein the lower section may have a smaller width than the upper section.

According to an embodiment of the present disclosure, there is provided a method of manufacturing an LDMOS semiconductor device, the method including forming a device isolation layer comprising a shallow trench isolation (STI) structure in a substrate; forming a pair of gate electrodes not directly connected to each other on the substrate; forming an interlayer insulating film on the substrate and the pair of gate electrodes; forming an etch stop layer on the interlayer insulating film; and forming a deep trench isolation (DTI) structure penetrating the etch stop layer, the interlayer insulating film, and the device isolation layer, wherein the DTI structure may extend along a width or similar lateral direction and be near or adjacent to longitudinal ends of the pair of gate electrodes.

According to another embodiment of the present disclosure, in the method of manufacturing an LDMOS semiconductor device, forming the DTI structure may include forming a first trench by etching the etch stop layer, the interlayer insulating film, and the device isolation layer; forming a second trench by etching the substrate below the first trench; depositing an insulating material on the etch stop layer and in the first trench and the second trench; and removing the insulating material on the etch stop layer.

According to still another embodiment of the present disclosure, the method of manufacturing an LDMOS semiconductor device may not form an extension region between a core region and an isolation region (e.g., of the LDMOS semiconductor device).

The present disclosure may have the following effects by one or more of the above configurations.

According to the present disclosure, by forming or including a deep trench isolation (DTI) region along the width direction of the LDMOS semiconductor device on a longitudinal boundary of the core region of the LDMOS semiconductor device, it is possible to maintain a high breakdown voltage, while reducing the chip size through non-formation or minimization of the extension region (e.g., between the core region and an isolation region of the LDMOS semiconductor device), and thus improve a degree of integration.

In addition, according to the present disclosure, by forming or including a DTI structure in a device isolation layer of the LDMOS semiconductor device, it is possible to prevent an increase in device size due to the formation or inclusion of the DTI structure.

Furthermore, according to the present disclosure, by forming a DTI structure in two stages, or including a DTI structure having an upper section and a lower section, the corresponding DTI structure can extend deeply into the substrate.

Meanwhile, it should be added that even if effects are not explicitly mentioned herein, the effects described in the following specification expected by the technical features of the present disclosure and their potential effects are treated as if they were described in the present specification.

### BRIEF DESCRIPTION OF THE DRAWINGS

The above and other objectives, features, and other advantages of the present disclosure will be more clearly understood from the following detailed description when taken in conjunction with the accompanying drawings, in which:

FIG. 1 is a plan view of a conventional LDMOS semiconductor device;

FIG. 2 is a plan view of an LDMOS semiconductor device according to an embodiment of the present disclosure;

FIG. 3 is a cross-sectional view of the LDMOS semiconductor device of FIG. 5 taken along line A-A′;

FIG. 4 is a cross-sectional view of the LDMOS semiconductor device of FIG. 2 taken along line B-B′;

FIG. 5 is a plan view of an LDMOS semiconductor device according to another embodiment of the present disclosure;

FIG. 6 is a plan view of an LDMOS semiconductor device according to yet another embodiment of the present disclosure; and

FIGS. 7 to 12 are views showing structures formed during a method of manufacturing an LDMOS semiconductor device according to one or more embodiments of the present disclosure.

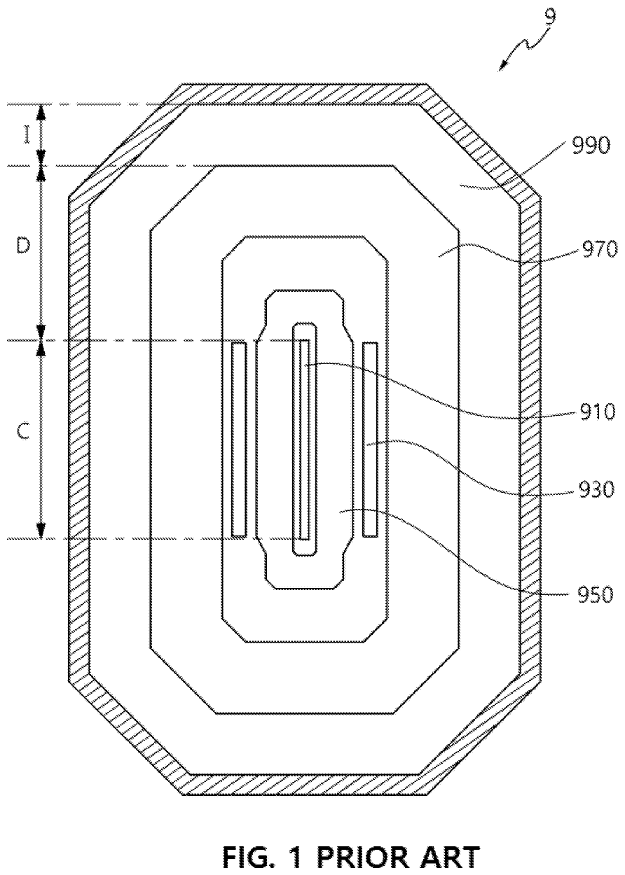

### DETAILED DESCRIPTION OF THE INVENTION

Hereinafter, embodiments of the present disclosure will be described in more detail with reference to the accompanying drawings. The embodiments of the present disclosure may be modified in various forms, and the scope of the present disclosure should not be construed as being limited to the following embodiments, but should be construed based on the matters described in the claims. In addition, these embodiments are provided for reference in order to more completely explain the present disclosure to those skilled in the art.

Hereinafter, it should be noted that when one component (or layer) is described as being on another component (or layer), the one component may be directly on the other component, or one or more additional components or layers may be between the one component and the other component. In addition, when one component is expressed as being directly on or above another component, no other components are between the one component and the other component. Moreover, being on “top”, “upper”, “lower”, “above”, “bottom” or “one (first) side” or “an opposite side” of a component means a relative positional relationship.

The terms first, second, third, etc. may be used to describe various items such as various components, regions and/or parts. However, the items are not limited by these terms.

In addition, it should be noted that, where certain embodiments are otherwise feasible, certain process sequences may be performed other than those described below. For example, two processes described in succession may be performed substantially simultaneously or in the reverse order.

The term “metal oxide semiconductor” (MOS) is a generally recognized term, and “M” is not limited to only metal and may comprise various types of conductors. Also, “S” may be a substrate or a semiconductor, and “O” is not limited to oxide and may include various types of organic or inorganic dielectric materials.

Moreover, the conductivity type of a doped region or component may be defined as “p-type” or “n-type” according to the main carrier characteristics, but this is only for convenience of description, and the technical spirit of the present disclosure is not limited to what is illustrated or specifically described. For example, hereinafter, “p-type” or “n-type” may be replaced with the more general terms “first conductivity type” or “second conductivity type”, and here, “first conductivity type” may refer to p-type, and “second conductivity type” may refer to n-type.

Furthermore, it should be understood that “lightly doped,” “heavily doped,” “high concentration” and “low concentration” referring to the doping concentration of an impurity region refers to the doping concentration of one component relative to other components.

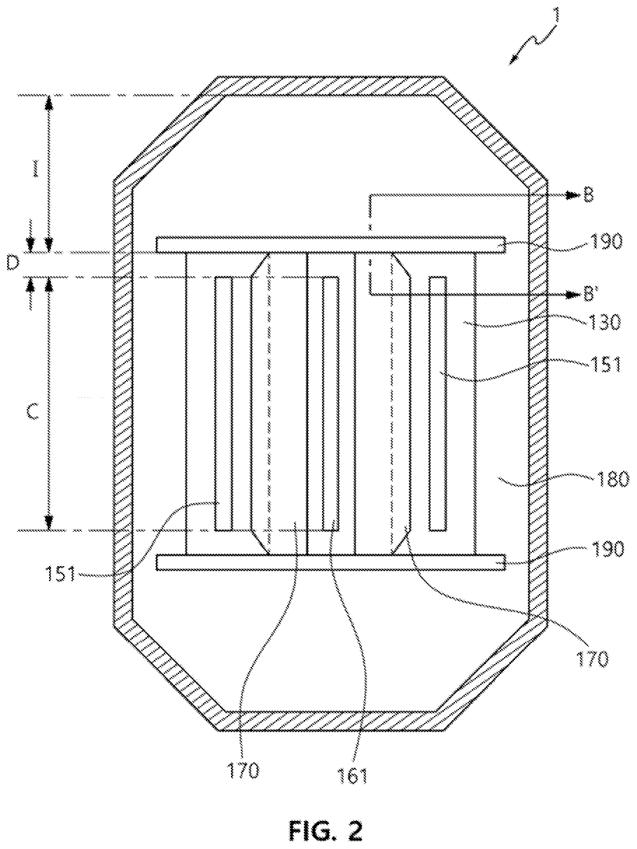

Hereinafter, it should be understood that the “width direction” means the x-axis direction in the plan views of FIGS. 2, 5 and 6, and the “longitudinal direction” means the y-axis direction in FIGS. 2, 5 and 6, orthogonal to the width direction.

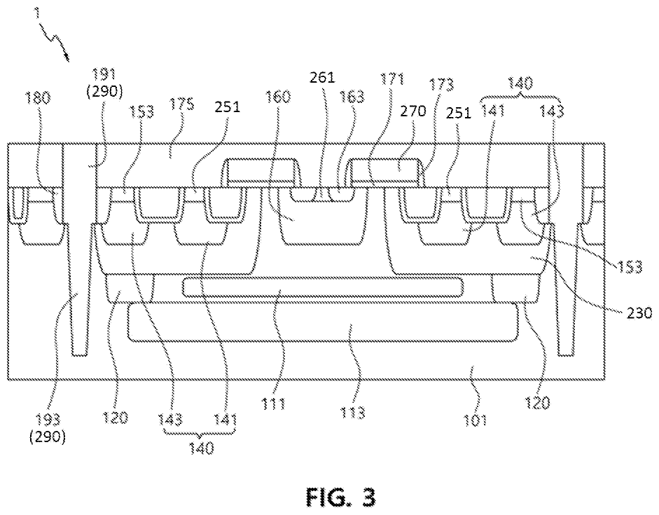

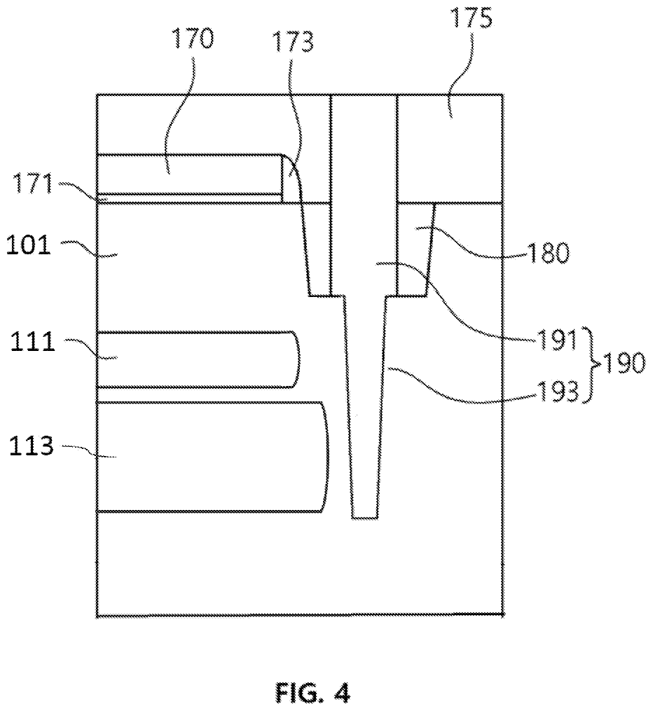

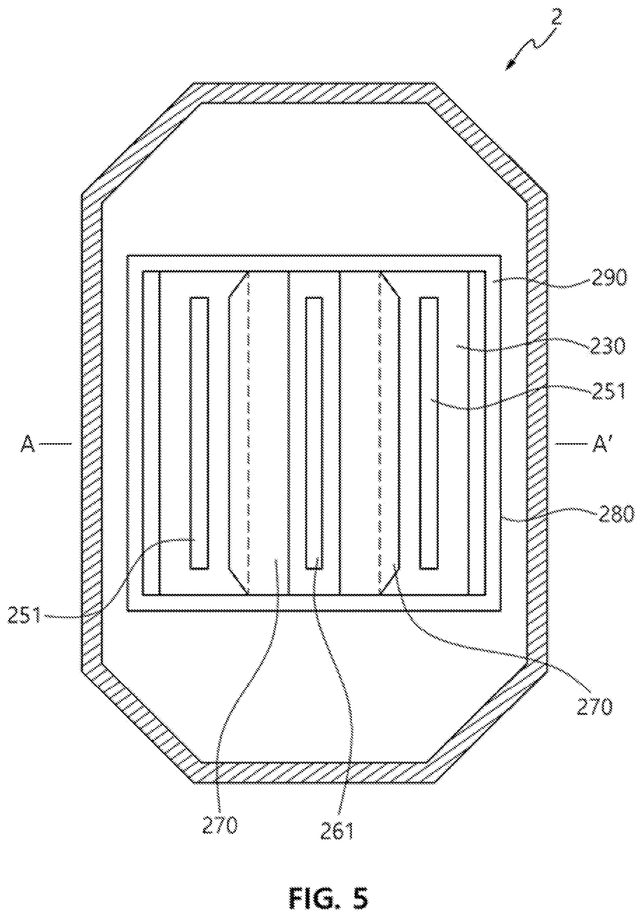

FIG. 2 is a plan view of an LDMOS semiconductor device according to an embodiment of the present disclosure, FIG. 3 is a cross-sectional view of the LDMOS semiconductor device of FIG. 5 taken along line A-A′, and FIG. 4 is a cross-sectional view of the LDMOS semiconductor device of FIG. 2 taken along line B-B′. For convenience of explanation, an interlayer insulating film 175 and some other components are omitted in FIG. 2.

Referring to FIG. 2, the present disclosure relates to an LDMOS semiconductor device 1 and, more particularly, to an LDMOS semiconductor device 1 seeking to maintain a high breakdown voltage while reducing the chip size through non-formation or minimization of an extension region D, and thus improving the degree of integration by forming or including a deep trench isolation (DTI) structure extending along the width direction, on or near a longitudinal boundary of the core region C or an isolation region I.

The LDMOS semiconductor device 1 according to an embodiment of the present disclosure includes a core region C which includes a channel between a source and drain to provide a current path when certain voltages are on the gate and the source; and isolation regions I at opposite ends of the core region C in the longitudinal direction (or of the extension regions D adjacent to the opposite ends of the core region C). In addition, a DTI structure 190 to be described later is (i) between the core region C and the isolation region I or (ii) in the isolation region I adjacent to the core region C or the extension region D, and the DTI structure 190 extends along the width direction. The DTI structure 190 limits the extension of the core region C in the longitudinal direction, and the extension regions D between the DTI structure 190 and the core region C may not be present or may have a minimal size.

As previously mentioned, in the conventional LDMOS device 9, since the electric field concentration at the ends of the source and the drains limits the breakdown voltage of the LDMOS device 9, an extension region D is between each of two opposite ends of the core region C and the adjacent isolation region I in the longitudinal direction, which becomes a factor in increasing the chip size.

In the LDMOS semiconductor device 1 according to the present disclosure, the DTI structure 190 is at, near or adjacent to an end of the core region C in the longitudinal direction, thereby minimizing the size of the extension region D or enabling the omission of the extension region D. A detailed description of this will be given later.

Referring to FIGS. 2 to 4, the LDMOS semiconductor device 1 according to the present disclosure includes a substrate 101. A well that may define at least in part an active region of the LDMOS semiconductor device 1 may be in the substrate 101, and the active region may be (further) defined at least in part by a device isolation layer 180. The substrate 101 may have a first conductivity type, may comprise a P-type diffusion region in a single-crystal silicon substrate, or may include a P-type epitaxial layer on a single-crystal silicon substrate.

The device isolation layer 180 may comprise a shallow trench isolation (STI) structure, and there is no separate limitation thereto. At least a portion of the device isolation layer 180 may have a shape surrounding elements of the core region C, and may extend along or form a closed path, for example.

A first buried layer 111 and a second buried layer 113 may be in the substrate 101. For example, the first buried layer 111 may overlap the second buried layer 113. In addition, a high voltage well 120 is connected to the second buried layer 113 (e.g., at one side or end thereof). The high voltage well 120 comprises an ion implantation region (HVNWELL) having the second conductivity type, and may be in the substrate 101 and connected to the second buried layer 113.

The aforementioned first buried layer 111 may comprise an impurity doped region having the first conductivity type, and the second buried layer 113 may comprise an impurity doped region having the second conductivity type. It should be noted that the first buried layer 111 and the high voltage well 120 are not essential components of the present disclosure and may be omitted in some cases. The first buried layer 111, the second buried layer 113, and the high voltage well 120 may be in the core region C.

A deep well 130 may be in the substrate 101 and over the high voltage well 120. The deep well 130 may be electrically connected to the high voltage well 120 (e.g., at an outermost side of the deep well 130) and may comprise an impurity doped region having the second conductivity type. The deep well 130 may be directly connected to the second buried layer 113 in some cases.

The deep well 130 is in the core region C and may be limited by the device isolation layer 180 and the DTI structure 190 at ends of the core region C along the longitudinal direction (see FIG. 4). In addition, if necessary, the deep well 130 may extend from the core region C into the extension region D along the longitudinal direction in the substrate 101 (see FIG. 4). At this time, unlike the case of the conventional semiconductor device 9, the deep well 130 does not form a ring or a closed path in the plan view (see FIG. 2). That is, the extension of the deep well 130 beyond the gate 170 may be limited by the DTI structure 190 along the longitudinal direction. Thus, the pair of deep wells 130 shown in FIGS. 2-4 are not directly and/or electrically connected to each other.

In the deep well 130, for example, a pair of wells 140 (141, 143) having the second conductivity type are spaced apart from each other. A drain 151/251 may be in the first well 141, and a heavily doped region 153 may be in the second well 143.

The drain 151/251 comprises an impurity doped region having the second conductivity type and may have a higher impurity concentration than the first well 141. The heavily doped region 153 also comprises a doped region having the second conductivity type and may have a higher impurity concentration than the second well 143. The drain 151/251 is confined within the core region C, and the heavily doped region 153 is also in the core region C.

The drain 151/251 and the heavily doped region 153 are preferably on the surface of the substrate 101. The heavily doped region 153, along with the second well 143, may function as a guard ring to reduce leakage current and improve SOA. The drain 151/251 may be electrically connected to a drain electrode (not shown), and the well 141 surrounding the drain 151/251 may comprise a drain extension region and may improve the breakdown voltage of the high voltage semiconductor device 1.

A body region 160 is in the substrate 101. The body region 160 comprises an impurity doped region having the first conductivity type and may be spaced apart from the deep well 130. For example, the body region 160 may be between the pair of deep wells 130. In addition, a source 161/261 is in the body region 160 and on the surface of the substrate 101. The source 161/261 comprises a region having a high concentration of second conductivity type impurities and may be electrically connected to a source electrode (not shown). In addition, a body contact region 163 may be in the body region 160, adjacent to or in contact with the source 161/261. The body contact region 163 may comprise a doped region with a high concentration of first conductivity type impurities. The source 161/261 and the body contact region 163 may be in the core region C. In addition, the body region 160 is in the core region C, but may also be in the extension region D if necessary.

A gate electrode 170/270 is on the substrate 101. To be specific, the gate electrode 170/270 may be between the drain 151/251 and the source 161/261 in, on or over the active region. The gate electrode 170/270 is on or over the channel, and the channel may be turned on or off by a voltage applied to the gate electrode 170/270. The gate electrode 170/270 may comprise, for example, conductive polysilicon, a metal, a conductive metal nitride, or a combination thereof, and may be formed by chemical vapor deposition (CVD), physical vapor deposition (PVD; e.g., sputtering), atomic layer deposition (ALD), metalorganic atomic layer deposition (MOALD), or metalorganic chemical vapor deposition (MOCVD).

A pair of gate electrodes 170/270 are apart from each other along the longitudinal direction in the core region C, and are not on the device isolation layer 180 or the DTI structure 190 in the isolation region I. Accordingly, the pair of gate electrodes 170/270 do not form a ring or a closed path (e.g., contacting each other) in the extension region D. If necessary, the gate electrode 170/270 may extend in the longitudinal direction into the extension region D.

A gate insulating film 171 is between the gate electrode 170/270 and the surface of the substrate 101. The gate insulating film 171 may comprise a silicon dioxide layer (e.g., a thermal oxide), a high-k dielectric layer, or a combination thereof. In addition, the gate insulating film 171 may be formed by ALD, CVD, wet or dry thermal oxidation, or PVD.

A sidewall of the gate electrode 170/270 may be covered with a gate spacer 173, and the gate spacer 173 may comprise an oxide film (e.g., silicon dioxide), a nitride film (e.g., silicon nitride), or a combination thereof (e.g., silicon oxynitride, a silicon nitride-on-silicon dioxide bilayer, etc.).

In addition, an interlayer insulating film 175 is on the substrate 101 and covering all of the gate electrodes 170/270. The interlayer insulating film 175 may comprise, for example, a borophosphosilicate glass (BPSG) and/or a silicon oxide formed from tetraethyl orthosilicate (TEOS), but the scope of the present disclosure is not limited thereto.

As described above, the device isolation layer 180 is in the isolation region I, and the device isolation layer 180 may surround the core region C.

The DTI structure 190/290 is the substrate 101, from the uppermost surface thereof to a predetermined depth. The DTI structure 190/290 may be at or near an end of the core region C in the longitudinal direction or adjacent to the end of the core region C, and may extend along the width direction. For example, ends of the DTI structure 190/290 in the width direction may extend to the device isolation layer 180 outside the deep well 130 in the width direction.

The DTI structure 190/290 may comprise a pair of DTI structures 190/290 not directly connected to each other, one each at opposite ends of the core region C in the longitudinal direction, or may form a ring or extend along a closed path. For example, a pair of DTI structures 190/290 may have a substantially quadrangular shape, having two opposing sides spaced apart along the longitudinal direction and two opposing sides extending along the width direction. This will be described in detail below.

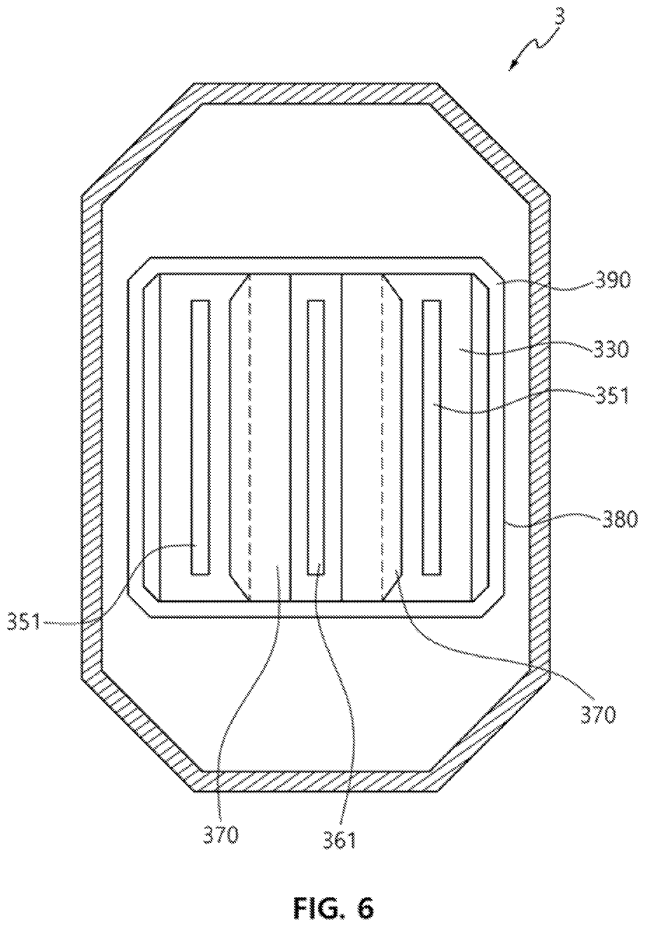

FIG. 5 is a plan view of an LDMOS semiconductor device according to another embodiment of the present disclosure, and FIG. 6 is a plan view of an LDMOS semiconductor device according to yet another embodiment of the present disclosure.

Referring to FIG. 5, in another embodiment, the DTI structure 290 may have a rectangular or frame shape and may surround the deep well 130. Referring to FIG. 6, in yet another embodiment, the DTI structure 290 may have a rectangular or octagonal shape, or a rectangular shape with cut corners. The above examples are only for explanation, and the scope of the present disclosure is not limited by the specific example.

In the embodiments shown in FIGS. 2 to 4, the DTI structure 190/290 may be at a boundary of the isolation region I, adjacent to the core region C. That is, the DTI structure 190/290 may overlap the device isolation layer 180 adjacent to the core region C. When the DTI structure 190/290 overlaps with the device isolation layer 180 as described above, an increase in device size may be avoided as much as possible.

The DTI structure 190/290 may comprise an upper section 191, which may be considered as a pre-DTI structure, and a lower section 193 that extends deeper into the substrate 101 than the device isolation layer 180. The upper section 191 may pass through or at least partially overlap the device isolation layer 180, and the lowermost surface of the upper section 191 may be at a depth in the substrate 101 that is substantially the same as the lowermost surface of the device isolation layer 180, for example. Thus, the lowermost surface of the upper section 191 may be adjacent to the lowermost surface of the device isolation layer 180.

In addition, the upper section 191 preferably has a width in a horizontal (e.g., width or longitudinal) direction less than that of the device isolation layer 180. The lower section 193 is below the upper section 191, and may be continuous with the upper section 191. The lower section 193 as a substantial DTI structure may be formed so that sides thereof are inclined to become narrower downward rather than extending straight in the vertical direction. This is because when the substrate 101 is etched, the etching strength is weakened according to the etching depth. On the other hand, the upper section 191 may extend downward with a substantially uniform width or may include a portion that widens downward, and there is no particular limitation thereto.

The lower section 193 may have a horizontal width less than that of the upper section 191. Both the upper section 191 and the lower section 193 may comprise the same material, or a material in the interlayer insulating film 175, but the scope of the present disclosure is not limited, and any insulating material may be used. The upper section 191 may have a shape in which an upper end thereof is adjacent or substantially adjacent to an upper end of the interlayer insulating film 175, and which penetrates the interlayer insulating film 180, or may extend only to a lower portion of the interlayer insulating film 175, and there is no particular limitation thereto. The bottom or lowermost surface of the lower section 193 is preferably deeper than the bottom or lowermost surface of the deep well 130.

The DTI structure 190/290 may be formed by forming a trench in a single process and filling the inside of the trench, or by forming two trenches for the DTI structure 190/290, one for the upper section 191, and one for the lower section 193 as in the present disclosure. However, when forming a DTI trench in one process, there are technical constraints on the trench depth. That is, when forming the DTI structure by etching of the substrate 101 in one process, it is not easy to form the DTI structure sufficiently deep. Moreover, in a subsequent process, it is also difficult to deposit the insulating material deep into the trench.

In order to prevent such problems, in the method of manufacturing LDMOS semiconductor device 1 according to the present disclosure, the DTI structure may be formed sufficiently deep by forming the trench for the upper section 191 with a relatively large width, and then forming the trench for the lower section 193 with a relatively narrow width using an additional etching process.

FIGS. 7 to 12 are views showing a method of manufacturing an LDMOS semiconductor device according to embodiments of the present disclosure.

Hereinafter, a method of manufacturing an LDMOS semiconductor device according to embodiments of the present disclosure will be described in detail with reference to the accompanying drawings. For convenience of description, processes for forming wells, buried layers, sources, and drains in the substrate, and gate electrodes on the substrate are omitted, and processes immediately before, during and immediately after the formation of the DTI structure 190 will be mainly explained.

First, referring to FIG. 7, the interlayer insulating film 175 is deposited on the substrate 101 and on the gate electrode 170. The interlayer insulating film 175 may be deposited by blanket deposition (e.g., CVD), followed by chemical mechanical polishing (CMP) to planarize the uppermost surface of the interlayer insulating film 175. As previously mentioned, the interlayer insulating film 175 may comprise, for example, a BPSG film and/or a TEOS film, but is not limited thereto. Then, an etch stop layer 177 is formed on the interlayer insulating film 175 (e.g., by blanket deposition). The etch stop layer 177 may be a CMP and/or etch stop layer for a subsequent CMP or etching process and may comprise, for example, SiN.

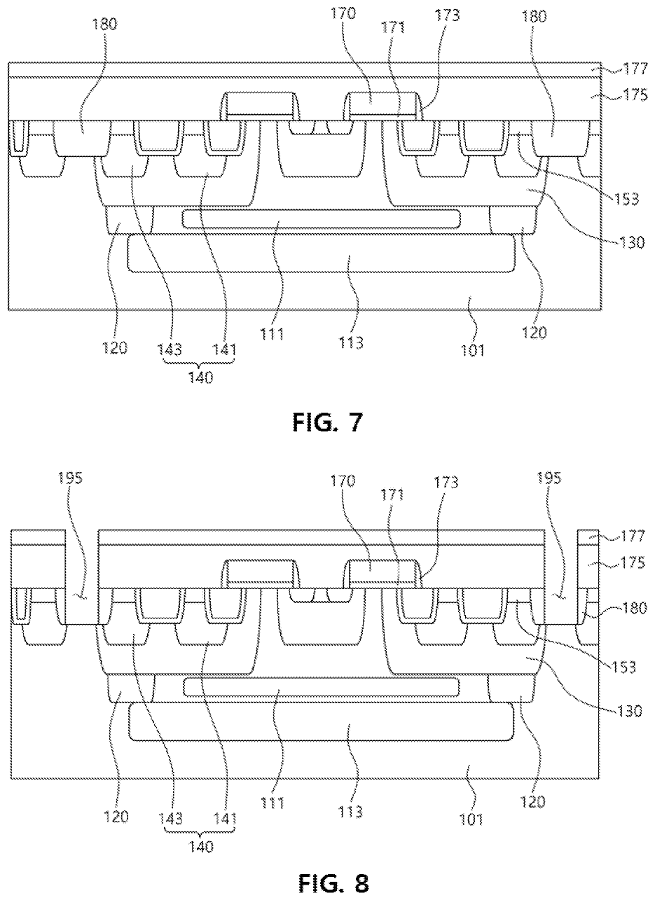

Thereafter, referring to FIG. 8, a first trench 195 for the upper section 191, which may be a pre-DTI structure, is formed by etching predetermined areas of the etch stop layer 177, the interlayer insulating film 175, and the device isolation layer 180. The first trench 195 partially overlaps and is generally formed within the borders of the device isolation layer 180, which is an STI structure. To be specific, a photoresist film (not shown) on the etch stop layer 177 is patterned to form openings for the first trench 193, for example. Then, by sequentially etching the etch stop layer 177, the interlayer insulating film 175, and the device isolation layer 180, the first trench 195 is formed.

After the first trench 195 is formed, the photoresist film is removed, which may comprise stripping the photoresist and cleaning the resulting structure.

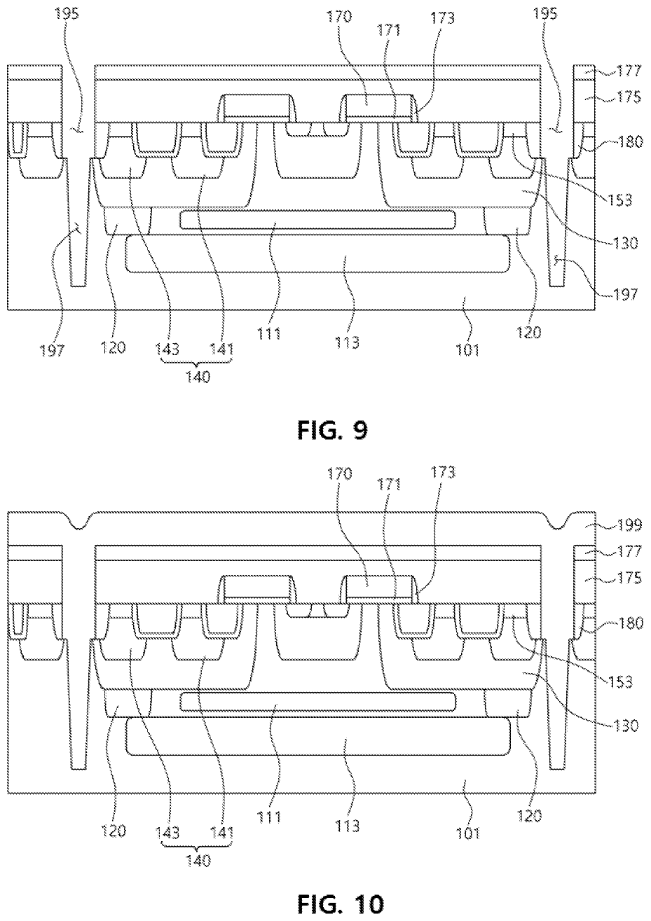

Thereafter, referring to FIG. 9, a second trench 197 for the lower section 193 is formed. The second trench 197 may be deeper than the device isolation layer 180. In addition, the second trench 197 has a smaller horizontal width than the first trench 195, and sidewalls of the second trench 197 may incline inward as a function of depth (e.g., as the sidewalls extend downward) or may have a substantially uniform width.

To be specific, a second photoresist film (not shown) on the etch stop layer 177 and along sidewalls of the first trench 195 is patterned, for example, to expose a surface of the substrate 101 in the first trench 195. That is, the photoresist film is patterned to form an opening having a width equal to the uppermost part of the second trench 197. Then, substrate 101 below the first trench 195 is etched to a deep position.

After forming the second trench 197, the photoresist film is removed by stripping and cleaning.

Thereafter, referring to FIG. 10, an insulating film 199 is deposited on the etch stop layer 177 and in the first trench 195 and the second trench 197. The insulating film 199 may comprise a TEOS film, but the scope of the present disclosure is not limited thereto and may be any oxide (e.g., silicon dioxide) and/or nitride (e.g., silicon nitride). During this process, the insulating film 199 is deposited on the etch stop layer 177. In addition, the insulating film 199 may fill the first trench 195 and the second trench 197.

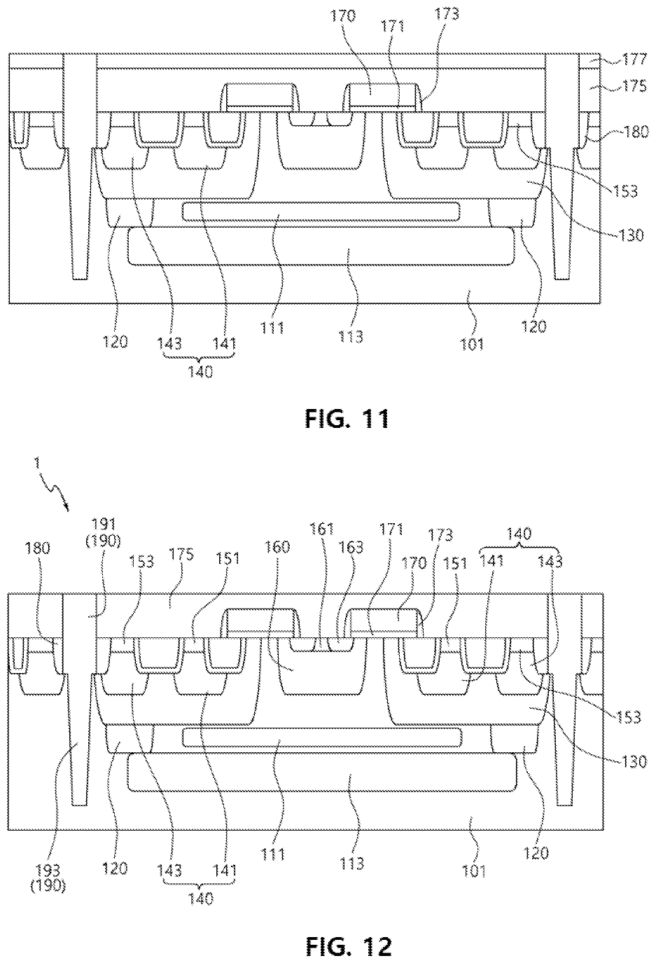

Thereafter, referring to FIG. 11, the insulating film 199 on the etch stop layer 177 is removed. Removing the insulating film 199 on the etch stop layer 177 may comprise etching (e.g., an etchback process) or CMP. When the insulating film 199 is completely removed from the etch stop layer 177, the resulting structure is cleaned. In this way, the DTI structure 190 may be completed. In the description above, the DTI structure 190 is formed by a single deposition of and CMP/etching process on the insulating film 199. However, the insulating film 199 may be deposited multiple times, and etch-back performed one time or more than one time (e.g., alternating with depositing a part of the insulating film 199), and the scope of the present disclosure is not limited by the specific example.

Thereafter, referring to FIG. 12, the etch stop layer 177 is removed (e.g., by etching), and the resulting structure is cleaned.

The above detailed description is illustrative of the present disclosure. In addition, the above description shows and describes preferred embodiments of the present disclosure, and the present disclosure can be used in various other combinations, modifications, and environments. That is, changes or modifications are possible within the scope of the concept of the disclosure herein, the scope equivalent to the written disclosure, and/or within the scope of skill or knowledge in the art. The above-described embodiments describe various states for implementing the technical idea(s) of the present disclosure, and various changes for the specific applications and/or fields of use of the present disclosure are possible. Accordingly, the detailed description of the present disclosure is not intended to limit the present disclosure to the disclosed embodiments.

What is claimed is:

1. A lateral double-diffused metal-oxide-semiconductor (LDMOS) semiconductor device, comprising:
a core region including a source and a drain spaced apart from each other;
an isolation region; and
an extension region between the core region and the isolation region,
wherein the core region comprises a pair of gate electrodes on opposite sides of the source and on a substrate, and
the pair of gate electrodes extend through the core region to the extension region and are not directly connected to each other.

2. The LDMOS semiconductor device of claim 1, wherein the isolation region comprises a deep trench isolation (DTI) structure at, adjacent or near to a boundary of the core region.

3. The LDMOS semiconductor device of claim 2, wherein the isolation region further comprises a device isolation layer, the device isolation layer comprises a shallow trench isolation (STI) structure, and the DTI structure at least partially overlaps the device isolation layer.

4. The LDMOS semiconductor device of claim 3, wherein the DTI structure comprises:
an upper section overlapping with the device isolation layer and having a smaller width than the device isolation layer; and
a lower section extending from the upper section.

5. The LDMOS semiconductor device of claim 4, wherein the lower section has a smaller width than the upper section.

6. An LDMOS semiconductor device, comprising:
a deep well, comprising a first impurity doped region in a substrate;
a first well and a second well, comprising second and third impurity doped regions in the deep well;
a drain in the first well;
a body region in the substrate, comprising a fourth impurity doped region spaced apart from the deep well;
a source in the body region;
a gate electrode on the substrate, spaced apart from the source and drain; and
a deep trench isolation (DTI) structure in the substrate,
wherein the gate electrode and the deep well have no closed path.

7. The LDMOS semiconductor device of claim 6, further comprising:
a device isolation layer surrounding the deep well.

8. The LDMOS semiconductor device of claim 6, wherein the DTI structure limits a longitudinal extension of the deep well.

9. The LDMOS semiconductor device of claim 6, wherein the DTI structure is in an isolation region and adjacent to a boundary with a core region.

10. The LDMOS semiconductor device of claim 9, comprising a pair of the DTI structures, one each on opposite ends or boundaries of the core region, the pair of DTI structures being spaced apart from each other, and extending along a width direction.

11. The LDMOS semiconductor device of claim 6, further comprising:
a first buried layer and a second buried layer in the substrate; and
a high voltage well connected to the second buried layer and a well.

12. An LDMOS semiconductor device, comprising:
a deep well in a core region, comprising a first impurity doped region in a substrate;
a first well comprising a second impurity doped region in the deep well;
a drain in the first well and in the core region;
a body region in the core region, comprising a third impurity doped region in the substrate;
a source in the body region and in the core region;
a gate electrode on the substrate;
a device isolation layer in each of two isolation regions and surrounding the deep well; and
a pair of deep trench isolation (DTI) structures, one in each of the isolation regions, near or adjacent to a boundary of the core region,
wherein the DTI structures are spaced apart along a length or similar longitudinal direction of the LDMOS semiconductor device.

13. The LDMOS semiconductor device of claim 12, wherein the pair of DTI structures are directly connected to each other.

14. The LDMOS semiconductor device of claim 12, wherein the pair of DTI structures extend substantially parallel along a width or similar lateral direction of the LDMOS semiconductor device.

15. The LDMOS semiconductor device of claim 12, wherein the gate electrode and the deep well have no closed path.

16. The LDMOS semiconductor device of claim 12, wherein the pair of DTI structures have ends in a width direction connected to each other on or in the device isolation layer.

17. The LDMOS semiconductor device of claim 12, wherein the DTI structure comprises:
an upper section at least partially overlapping the device isolation layer, and having a smaller width than the device isolation layer; and
a lower section continuous with the upper section and having an end deeper than a lowermost surface of the upper section,
wherein the lower section has a smaller width than the upper section.

18. A method of manufacturing an LDMOS semiconductor device, the method comprising:
forming a device isolation layer comprising a shallow trench isolation (STI) structure in a substrate;
forming a pair of gate electrodes not directly connected to each other on the substrate;
forming an interlayer insulating film on the substrate and the pair of gate electrodes;
forming an etch stop layer on the interlayer insulating film; and
forming a deep trench isolation (DTI) structure penetrating the etch stop layer, the interlayer insulating film, and the device isolation layer,
wherein the DTI structure extends along a width or similar lateral direction and is near or adjacent to longitudinal ends of the pair of gate electrodes.

19. The method of claim 18, wherein forming the DTI structure comprises:
forming a first trench by etching the etch stop layer, the interlayer insulating film, and the device isolation layer;
forming a second trench by etching the substrate below the first trench;
depositing an insulating material on the etch stop layer and in the first trench and the second trench; and
removing the insulating material on the etch stop layer.

20. The method of claim 18, wherein the method does not form an extension region between a core region and an isolation region.
